(19) United States
(12) Patent Application Publication
(10) Pub. No.: US 2025/0219008 A1
(43) Pub. Date: Jul. 3, 2025

(54) ELECTRONIC MODULES HAVING ELECTRICAL CONNECTION ELEMENTS IN THE FORM OF WEDGE-WEDGE-BONDED STRUCTURES NOT CONSISTING OF SOLID METAL MATERIAL

(71) Applicant: Heraeus Electronics GmbH & Co. KG, Hanau (DE)

(72) Inventors: Marcel NEUBAUER, Hanau (DE); Frank KRÜGER, Hanau (DE); Christian KERSTING, Hanau (DE); Juergen SCHARF, Hanau (DE); Magnus KEIL, Hanau (DE)

(21) Appl. No.: 18/850,350

(22) PCT Filed: Oct. 24, 2022
(86) PCT No.: PCT/EP2022/079525

§ 371 Date: Sep. 24, 2024

(30) Foreign Application Priority Data
Mar. 29, 2022 (EP) 22164896.7

(51) Int. Cl. H01L 23/00

(52) U.S. Cl. CPC H01L 24/45; H01L 24/48; H01L 24/85; H01L 2224/45014; H01L 2224/45026; H01L 2224/45124; H01L 2224/45139; H01L 2224/45144; H01L 2224/45147; H01L 2224/45164; H01L 2224/48151; H01L 2224/48472; H01L 2224/85986

(57) ABSTRACT

An electronic module comprising one or more assemblies each consisting of a first electronic component with a first contact surface with a first end, wedge-bonded on this first contact surface, and a second electronic component with a second contact surface with a second end, wedge-bonded on this second contact surface, wherein the originally free structure not made of solid metal material is a structure (i) in the form of a ribbon made from warp-knitted, weft-knitted, woven or braided fine metal wire and having a cross-sectional area within a range of 25,000 to 800,000 μm², or (ii) in the form of a cable made from stranded fine metal wire and having a cross-sectional area within a range of 8,000 to 600,000 μm², or (iii) in the form of a tube made from circular-warp-knitted or circular-weft-knitted fine metal wire and having a cross-sectional area within a range of 8,000 to 600,000 μm².

The invention relates to electronic modules with wedge-wedge-bonded structures not made of solid metal material as electrical connecting elements.

The electronic modules mentioned herein are preferably those in the field of power electronics, i.e., they are preferably so-called power modules.

Thick bonding wires and bonding ribbons of solid metal material are known to a person skilled in the art as electrical connecting elements in the field of electronics. They are used in particular as electrical connecting elements in the field of assembly and connection technology for electronic modules, especially power modules. The high currents in the field of power electronics require large cross-sections of thick bonding wires and bonding ribbons compared to the cross-sections as exist with thin bonding wires in the field of microelectronics. However, the greater the cross-section, the greater the rigidity, which is accompanied by reduced flexibility of the relevant bonded joint.

US 2019/006126 A1 discloses a first ultracapacitor having a first terminal, a second ultracapacitor having a second terminal, and a connecting strip that contains a center section which is positioned between a first attachment section and a second attachment section, wherein the first terminal of the first ultracapacitor is connected to the first attachment section of the connecting strip, and the second terminal of the second ultracapacitor is connected to the second attachment section of the connecting strip, and further wherein the center section is formed from a flexible conductive material. The flexible conductive material can be in the form of metal wire mesh. US 2019/006126 A1 further discloses that the first attachment section can define a first opening through which the first terminal is received, and the second attachment section can define a second opening through which the second terminal is received. With respect to the actual attachment, US 2019/006126 A1 teaches the use of attachment devices such as nuts, washers, bolts, screws, compression or expansion fittings, etc. The attachment devices can be further connected to the attachment sections (e.g., welded, glued, ultrasonically bonded, etc.) to ensure that they remain securely connected to the ultracapacitors. Alternatively, the attachment devices could be omitted, and the connecting strip could be joined just by using other techniques, such as welding.

JP 2003-331655 discloses flexible flat cable consisting of a plurality of metal threads knitted together. The flexible flat cable can be used in an automobile airbag system.

The problem of the invention was to provide an electrically conductive connection technique as an alternative to the aforementioned prior art in the field of assembly and connection technology for electronic modules.

The problem can be solved by using wedge-wedge-bonded structures that are not made of solid metal material as electrical connecting elements in electronic modules. In other words, the problem can be solved by means of one or more assemblies within electronic modules as described in more detail below, wherein the assemblies comprise wedge-wedge-bonded structures that are not made of solid metal material. The wedge-wedge-bonded structures not made of solid metal material serve as electrical connecting elements. In this respect, the solution to the problem also comprises electronic modules which comprise one or more electrical connecting elements in the form of wedge-wedge-bonded structures not made of solid metal material. The solution to the problem also comprises a method for producing such electronic modules.

Said structures not made of solid metal material each have two ends; as mentioned, the latter are wedge-bonded so that they can be called wedge-wedge-bonded structures not made of solid metal material. In the following, a distinction is made between free or originally free structures not made of solid metal material [structures not made of solid metal material that are not yet attached at or with their two ends; hereinafter also referred to as “free structures” or “originally free structures” for short] and wedge-wedge-bonded structures not made of solid metal material [structures wedge-wedge bonded at or with their two ends (attached by wedge-wedge bonding) not made of solid metal material; hereinafter also referred to as “wedge-wedge-bonded structures” for short]. In other words, the wedge-wedge-bonded structures can be formed from the originally free structures by wedge-bonding their two ends; as a result, the wedge-wedge-bonded structures comprise a center section between their two wedge-bonded ends.

The originally free as well as the wedge-wedge-bonded structures are characterized by a lower stiffness compared to conventional thick bonding wires or bonding ribbons made of solid metal material; an increased flexibility of a wedge-wedge bond is made possible and thus, for example, a wedge-wedge oblique bond. The wedge-wedge-bonded structures can allow more complex loop formation, i.e., achieve previously technically impossible loop shapes; for example, flatter angles are possible for a lower inductance structure as well as three-dimensional, complex shaping. Furthermore, the mechanical load on the specific wedge bond point can be reduced, and the service life of a wedge-wedge bond connection can thereby be increased.

As mentioned, the electronic modules according to the invention comprise one or more electrical connecting elements in the form of wedge-wedge-bonded structures not made of solid metal material. More specifically, an electronic module according to the invention comprises one or more assemblies, each consisting of a total of two contact surfaces of two electronic components and a structure not made of solid metal material connecting the two contact surfaces of the two electronic components via its two wedge-bonded ends. In other words, an electronic module according to the invention comprises one or more assemblies, each consisting of a first contact surface of a first electronic component with a first end of an originally free structure not made of solid metal material wedge-bonded thereto, and a second contact surface of a second electronic component with a second end of the originally free structure wedge-bonded thereto. To put it another way, an electronic module according to the invention comprises one or more assemblies, each consisting of a first electronic component with a first contact surface with a first end, wedge-bonded on this first contact surface, of an originally free structure not made of solid metal material, and a second electronic component with a second contact surface with a second end, wedge-bonded on this second contact surface, of the originally free structure not made of solid metal material. The originally free structure not made of solid metal material is a structure (i) in the form of a ribbon made from warp-knitted, weft-knitted, woven or braided fine metal wire and having a cross-sectional area within a range of 25,000 to 800,000 μm^{2,} or (ii) in the form of a cable made from stranded fine metal wire and having a cross-sectional area within a range of 8,000 to 600,000 μm^{2,} or (iii) in the form of a tube made from circular-warp-knitted or circular-weft-knitted fine metal wire and having a cross-sectional area within a range of 8,000 to 600,000 μm^{2.}

It should be emphasized once again that the electronic modules according to the invention are also preferably power modules; accordingly, the electronic components in the case of power modules are in particular electronic components for power electronics.

Examples of the aforementioned electronic components which each possess at least one contact surface comprise substrates and active electronic components. For example, the aforementioned first electronic component can be a substrate, and the aforementioned second electronic component can be an active electronic component. Examples of substrates comprise IMS substrates (insulated metal substrates), metal ceramic substrates such as AMB substrates (active metal brazed substrates), DCB substrates (direct copper bonded substrates), PCBs (printed circuit boards), and lead frames. Examples of active electronic components comprise diodes, IGBTs (insulated-gate bipolar transistors) and MOSFETs (metal-oxide-semiconductor field-effect transistors).

The originally free structures not made of solid metal material are, as mentioned above, structures (i) in the form of a ribbon made from warp-knitted, weft-knitted, woven or braided fine metal wire and having a cross-sectional area within a range of 25,000 to 800,000 μm^{2,} or (ii) in the form of a cable made from stranded fine metal wire and having a cross-sectional area within a range of 8,000 to 600,000 μm^{2,} or (iii) in the form of a tube made from circular-warp-knitted or circular-weft-knitted fine metal wire and having a cross-sectional area within a range of 8,000 to 600,000 μm^{2.}

To avoid misunderstandings, the cross-sectional area of the originally free structures mentioned herein does not represent a cross-section through a solid metal material and accordingly does not represent a completely metallic cross-section, but also comprises hollow parts in addition to cross-cut fine metal wire.

The originally free structures in ribbon form are not to be confused with bonding ribbons made of solid metal material; they are also hereinafter referred to as “ribbons” for short.

The originally free structures in cable form are not to be confused with thick bonding wires made of solid metal material; they are also referred to as “cables” for short.

The originally free structures in tubular form, where there is no risk of confusion with bonding ribbons made of solid metal material, are also hereinafter referred to as “tubular networks” for short.

The originally free structures are not made of solid metal material like the well-known thick bonding wires or bonding ribbons, but rather, depending on the embodiment (i), (ii) or (iii), of warp-knitted, weft-knitted, woven, braided, stranded, circular-warp-knitted or circular-weft-knitted fine metal wire. One or more types of fine metal wire can be connected together to form a warp-knitted fabric, a weft-knitted fabric, a woven fabric, a braided fabric, a cable, a circular-warp-knitted fabric or a circular-weft-knitted fabric, wherein the warp-knitted fabric, weft-knitted fabric, woven fabric and braided fabric are realized as a flat ribbon-shaped network, and wherein the circular-warp-knitted fabric and circular-weft-knitted fabric are realized as a tubular network. Not only are all embodiments of the tubular networks permeable to gases, but also all embodiments of the cables and ribbons are not a solid metal material and are therefore also permeable to gases, i.e., they are permeable to gases with practically no resistance and without requiring diffusion processes. They also have in common that their individual fine metal wires touch each other; they allow an electrical current to flow in the longitudinal direction (perpendicular to the cross-sectional area of an originally free structure).

The expression “a type of fine metal wire” can refer both to the material, or more precisely to the metal, and to the wire cross-section; in the case of round fine metal wire, to the material and to the wire diameter. Examples of material types comprise, in particular, copper and copper-based alloys [copper alloys with a copper content >98 wt % (weight%), preferably >99 wt %], silver and silver-based alloys (silver alloys with a silver content >95 wt %, preferably >99 wt %), aluminum and aluminum-based alloys (aluminum alloys with an aluminum content >98 wt %, preferably >99 wt %), gold-coated silver (silver or silver alloy core with gold coating), aluminum-coated copper (copper or copper alloy core with aluminum coating), palladium-coated copper (copper or copper alloy core with palladium coating). Accordingly, the fine metal wire or wires constituting an originally free structure can be selected from the group consisting of fine metal wires of copper, copper-based alloys, silver, silver-based alloys, aluminum, aluminum-based alloys, gold-coated silver, aluminum-coated copper and palladium-coated copper. The wire cross-section of a fine metal wire can be within a range of 1,950 to 71,000 μm^{2,} for example. The wire diameter of a fine metal wire with a round cross-section can be within a range of 50 to 300 μm, for example. If an originally free structure comprises several types of fine metal wires, this means that it comprises at least two different fine metal wires which differ from one another in their type of material, and/or in the shape of their cross-section, and/or in their cross-sectional area.

Each of the embodiments of warp-knitted fabric, weft-knitted fabric, woven fabric, braided fabric, cable, circular-warp-knitted fabric and circular-weft-knitted fabric can be made from individually processed or initially twisted fine metal wires.

The one or more types of fine metal wire connected together to form a warp-knitted fabric, a weft-knitted fabric, a woven fabric, a braided fabric, a cable, a circular-warp-knitted fabric or a circular-weft-knitted fabric can have an overall homogeneous assembly or distribution in the cable or in the network. However, they can also have an inhomogeneous and yet symmetrical distribution in the network; for example, an originally free cable or network consisting of aluminum and copper fine wire can be designed in such a way that the aluminum fine wire portion substantially makes up the region of the outer surface, while the portion of copper fine wire is substantially located on the inside as the core of the cable or network.

The structures (originally free structures, wedge-wedge-bonded structures) do not comprise any electrical insulating material, i.e., neither as a structure nor with regard to the fine metal wire comprised by the structure.

Structures of type (i), i.e., ribbons, can have a cross-sectional area described by a substantially rectangular outline, for example with an area within a range of 25,000 to 800,000 μm^{2.} An envelope of the outline of the cross-sectional area can describe the smallest possible rectangle. The width/thickness ratio of the smallest possible rectangle can lie within a range of 20:1 to >1:1, for example.

A distinction is made here between an envelope of the outline of the cross-sectional area of an originally free structure and the outline of the cross-sectional area of an originally free structure. To avoid misunderstandings, while said outline (outline in descriptive geometry) can for example be formed by a wavy or jagged line, the envelope on the other hand means a straight line that encloses said outline in the sense of a smallest possible rectangle. Consequently, the smallest possible rectangular area described by the envelope is slightly larger than the cross-sectional area defined by the outline.

The cross-sectional area of a ribbon is formed by the cross-cut warp-knitted, weft-knitted, woven or braided fine metal wires, i.e., the cross-sectional area is substantially filled with metal, but also comprises the aforementioned hollow parts.

According to a first method variant, the ribbons can be produced directly by warp-knitting, weft-knitting, weaving or braiding fine metal wire as flat networks with the desired dimensions and, if necessary, subsequently rolled flat.

According to a second method variant, the ribbons can also be produced by warp-knitting, weft-knitting, weaving or braiding fine metal wire into flat structures, followed by cutting to a desired size. The cutting can be done mechanically or by laser cutting. Cut edges can be welded if necessary. Laser cutting can involve laser welding of cut edges in the same step. Finally, flat rolling can follow if necessary.

According to a third method variant, the ribbons can also be produced by circular-warp-knitting or circular-weft-knitting of fine metal wire as special techniques of warp-knitting or weft-knitting fine metal wire, followed by subsequent flat rolling of the resulting circular-warp-knitted fabric or circular-weft-knitted fabrics; in this case, the tubular networks are necessarily rolled flat.

The optional or necessary flat rolling to form the ribbons is usefully carried out in such a way that compression takes place, but preferably substantially without deforming the cross-sectional shape of the fine metal wire or wires that make up the ribbons. Flat rolling can result in the formation of two semicircular bulges pointing outwards on the opposite broad sides defining the thickness of the strip, i.e., a substantially rectangular cross-sectional area then has said semicircular bulges; the latter can have a radius that does not exceed the thickness of the ribbon. The formation of such semicircular bulges can be deliberately pursued or deliberately prevented; in the latter case for example by a lateral infeed during flat rolling, for example by using lateral rollers with a set roller gap.

Structures of type (ii), i.e., cables, can have a cross-sectional area described by a substantially round outline, for example with an area within a range of 8,000 to 600,000 μm^{2.} An envelope of the outline of the cross-sectional area can describe the smallest possible rectangle and in particular a smallest possible square. Cables that have undergone flat rolling can have a cross-sectional area described by an outline substantially in the shape of a rectangle with two semicircular bulges pointing outwards, for example with an area within a range of 8,000 to 600,000 μm^{2.} An envelope of the outline of the cross-sectional area can describe the smallest possible rectangle.

As already mentioned, to avoid misunderstandings, while said outline can be formed by a wavy or jagged line, for example, the envelope on the other hand means a straight line which encloses said outline in the sense of a smallest possible square or a smallest possible rectangle.

The cross-sectional area of a cable is formed by the cross-cut stranded fine metal wires, i.e., the cross-sectional area is substantially filled with metal, but also comprises the aforementioned hollow parts.

The cables can be produced directly by stranding fine metal wire, and then rolled flat if necessary.

The optional flat rolling is usefully carried out in such a way that compression occurs, but preferably substantially without deforming the cross-sectional shape of the fine metal wire or wires that make up the cables.

Structures of type (iii), i.e., tubular networks, can have a cross-sectional area described by a substantially round outline, for example with an area within a range of 8,000 to 600,000 μm^{2.} An envelope of the outline of the cross-sectional area can describe the smallest possible rectangle and in particular a smallest possible square. Tubular networks which have undergone roll forming while avoiding flat rolling can have a cross-sectional area described by an outline substantially in the shape of a rectangle with two semicircular bulges pointing outwards, for example with an area within a range of 8,000 to 600,000 μm^{2.} An envelope of the outline of the cross-sectional area can describe the smallest possible rectangle.

As already mentioned, to avoid misunderstandings, while said outline can be formed by a wavy or jagged line, for example, the envelope on the other hand means a straight line which encloses said outline in the sense of a smallest possible square or a smallest possible rectangle.

A tubular network is naturally hollow. Its cross-sectional area is formed by the cross-cut circular-warp-knitted or circular-weft-knitted fine metal wires located only in the edge region, while it has a comparatively high proportion of hollow space, especially in the center or inside.

The tubular networks can be produced directly by circular-warp-knitting or circular-weft-knitting fine metal wire and, if necessary, then carefully roll-formed while maintaining a hollow tubular shape, but in any case avoiding complete flat rolling.

The optional gentle roll forming is usefully carried out in such a way that compression takes place while maintaining a hollow tube shape and substantially without deforming the cross-sectional shape of the fine metal wire or wires that make up the tubular networks.

The originally free structures have two ends that are still unattached. After their production, the originally free structures can have a length of for example within a range of 50 to 50,000 meters, preferably 100 to 500 meters. For example, they can be stored rolled up and cut into pieces by the user with a length for example withing a range of 0.5 to 5 centimeters during wedge-wedge bonding. Each of these pieces intended for wedge-wedge bonding is itself an originally free structure.

The wedge-wedge-bonded structures have two wedge-bonded ends (attached by wedge bonding). The particular wedge bonding point is a wedge bonding point created directly by wedge bonding, i.e., a wedge bonding point created without the use of any additional aids such as attachment devices. Their length between the two wedge-bonded ends, i.e., the length of their center section, typically lies within a range of 0.4 to 4.5 centimeters.

The wedge-wedge-bonded structures each connect two corresponding contact surfaces (e.g., bond pads) of two electronic components of an electronic module according to the invention, just as conventional prior art wedge-wedge-bonded thick bonding wires or bonding ribbons made of solid metal material do. In other words, with the wedge-wedge-bonded structures, it is the merit of the invention to provide not only an advantageous replacement for conventional wedge-wedge-bonded thick bonding wires or bonding ribbons made of solid metal material, but also, it is surprisingly possible to successfully use such an originally free structure, which is still unattached on or with its two ends, to produce an electronic module comprising an aforementioned assembly or one or more such assemblies, i.e., to connect it to two corresponding contact surfaces of two electronic components by means of wedge-wedge bonding. Needless to say that, for the person skilled in the art, wedge-wedge bonding excludes the use of attachment devices such as those addressed in US 2019/006126 A1.

The wedge-wedge bonding as such is practically no different from the wedge-wedge bonding known to a person skilled in the art and used in the case of thick bonding wires and bonding ribbons made of solid metal material, for example wedge-wedge bonding with ultrasonic support and/or with laser support.

The invention therefore also relates to the use of a free structure, which is still unattached at its two ends and is not made of solid metal material, for producing one of said assemblies by wedge-bonding one of the two ends to a contact surface of a first electronic component (first contact surface of a first electronic component) and wedge-bonding the other of the two ends to a contact surface of a second electronic component (second contact surface of a second electronic component), wherein the free structure which is still unattached at its two ends and is not made of solid metal is a structure (i) in the form of a ribbon made from warp-knitted, weft-knitted, woven or braided fine metal wire and having a cross-sectional area within a range of 25,000 to 800,000 μm^{2,} or (ii) in the form of a cable made from stranded fine metal wire and having a cross-sectional area within a range of 8,000 to 600,000 μm^{2,} or (iii) in the form of a tube made from circular-warp-knitted or circular-weft-knitted fine metal wire and having a cross-sectional area within a range of 8,000 to 600,000 μm^{2.} All of the aforementioned applies with regard to embodiments (i), (ii) and (iii) of the structure.

The method for producing said one or more assemblies of an electronic module according to the invention comprises the following steps for each assembly:
(1) Providing two electronic components, each with one of a total of two contact surfaces to be connected to each other (providing a first electronic component with a first contact surface and a second electronic component with a second contact surface to be connected to the first contact surface of the first electronic component),
(2) Providing a free structure that is still unattached at its two ends and is not made of solid metal material,
(3) Wedge-bonding one of the two ends to one of the two contact surfaces to be connected to each other, and
(4) Wedge-bonding the other end to the other of the two contact surfaces to be connected to each other,
wherein the free structure which is still unattached at its two ends and is not made of solid metal material is a structure (i) in the form of a ribbon made from warp-knitted, weft-knitted, woven or braided fine metal wire and having a cross-sectional area within a range of 25,000 to 800,000 μm^{2,} or (ii) in the form of a cable made from stranded fine metal wire and having a cross-sectional area within a range of 8,000 to 600,000 μm^{2,} or (iii) in the form of a tube made from circular-warp-knitted or circular-weft-knitted fine metal wire and having a cross-sectional area within a range of 8,000 to 600,000 μm^{2.} All of the aforementioned applies with regard to embodiments (i), (ii) and (iii) of the structure.

The method for producing an electronic module according to the invention in turn comprises producing one or more assemblies of the electronic module, comprising the following steps for each assembly:
(1) Providing two electronic components of the assembly, each with one of a total of two contact surfaces to be connected to each other (providing a first electronic component of the assembly with a first contact surface and a second electronic component of the assembly with a second contact surface to be connected to the first contact surface of the first electronic component),
(2) Providing a free structure that is still unattached at its two ends and is not made of solid metal material,
(3) Wedge-bonding one of the two ends to one of the two contact surfaces to be connected to each other, and
(4) Wedge-bonding the other end to the other of the two contact surfaces to be connected to each other,
wherein the free structure which is still unattached at its two ends and is not made of solid metal material is a structure (i) in the form of a ribbon made from warp-knitted, weft-knitted, woven or braided fine metal wire and having a cross-sectional area within a range of 25,000 to 800,000 μm^{2,} or (ii) in the form of a cable made from stranded fine metal wire and having a cross-sectional area within a range of 8,000 to 600,000 μm^{2,} or (iii) in the form of a tube made from circular-warp-knitted or circular-weft-knitted fine metal wire and having a cross-sectional area within a range of 8,000 to 600,000 μm^{2.} All of the aforementioned applies with regard to embodiments (i), (ii) and (iii) of the structure.

1. An electronic module comprising one or more assemblies each consisting of a first electronic component with a first contact surface with a first end, wedge-bonded on this first contact surface, of an originally free structure not made of solid metal material, and a second electronic component with a second contact surface with a second end, wedge-bonded on this second contact surface, of the originally free structure not made of solid metal material, wherein the originally free structure not made of solid metal material is a structure (i) in the form of a ribbon made from warp-knitted, weft-knitted, woven or braided fine metal wire and having a cross-sectional area within a range of 25,000 to 800,000 μm^{2,} or (ii) in the form of a cable made from stranded fine metal wire and having a cross-sectional area within a range of 8,000 to 600,000 μm^{2,} or (iii) in the form of a tube made from circular-warp-knitted or circular-weft-knitted fine metal wire and having a cross-sectional area within a range of 8,000 to 600,000 μm^{2.}

2. The electronic module according to claim 1, wherein the electronic module is a power module.

3. The electronic module according to claim 1, wherein the first electronic component is a substrate, and wherein the second electronic component is an active electronic component.

4. The electronic module according to claim 1, wherein one or more types of fine metal wire are connected together to form the warp-knitted fabric, weft-knitted fabric, woven fabric, braided fabric, cable, circular-warp-knitted fabric or circular-weft-knitted fabric.

5. The electronic module according to claim 1, wherein the fine metal wire or wires constituting the structure are selected from the group consisting of fine metal wires of copper, copper-based alloys, silver, silver-based alloys, aluminum, aluminum-based alloys, gold-coated silver, aluminum-coated copper and palladium-coated copper.

6. The electronic module according to claim 1, wherein the fine metal wire or wires constituting the structure each have a wire cross-section within a range of 1,950 to 71,000 μm^{2.}

7. A use of a free structure, still unattached at its two ends and not made of solid metal material, for producing an assembly consisting of a first electronic component with a first contact surface with a first end, wedge-bonded on this first contact surface, of the originally free structure which is still unattached at its two ends and is not made of solid metal material, and a second electronic component with a second contact surface with a second end, wedge-bonded on this second contact surface, of the originally free structure which is still unattached at its two ends and is not made of solid metal material, by wedge-bonding the first end to the first contact surface of the first electronic component and wedge-bonding the second end to the second contact surface of the second electronic component, wherein the free structure which is still unattached at its two ends and is not made of solid metal material is a structure (i) in the form of a ribbon made from warp-knitted, weft-knitted, woven or braided fine metal wire and having a cross-sectional area within a range of 25,000 to 800,000 μm^{2,} or (ii) in the form of a cable made from stranded fine metal wire and having a cross-sectional area within a range of 8,000 to 600,000 μm^{2,} or (iii) in the form of a tube made from circular-warp-knitted or circular-weft-knitted fine metal wire and having a cross-sectional area within a range of 8,000 to 600,000 μm^{2.}

8. A method for producing an electronic module according to claim 1 comprising the production of one or more assemblies of the electronic module, wherein the following steps are comprised per assembly:
(1) Providing a first electronic component of the assembly with a first contact surface and a second electronic component of the assembly with a second contact surface to be connected to the first contact surface of the first electronic component,
(2) Providing a free structure that is still unattached at its two ends and is not made of solid metal material,
(3) Wedge-bonding one of the two ends to one of the two contact surfaces to be connected to each other, and
(4) Wedge-bonding the other end to the other of the two contact surfaces to be connected to each other,
wherein the free structure which is still unattached at its two ends and is not made of solid metal material is a structure (i) in the form of a ribbon made from warp-knitted, weft-knitted, woven or braided fine metal wire and having a cross-sectional area within a range of 25,000 to 800,000 μm^{2,} or (ii) in the form of a cable made from stranded fine metal wire and having a cross-sectional area within a range of 8,000 to 600,000 μm^{2,} or (iii) in the form of a tube made from circular-warp-knitted or circular-weft-knitted fine metal wire and having a cross-sectional area within a range of 8,000 to 600,000 μm^{2.}

9. The method according to claim 8, wherein the electronic module is a power module.

10. The method according to claim 8, wherein the first electronic component is a substrate, and wherein the second electronic component is an active electronic component.

11. The method according to claim 8, wherein one or more types of fine metal wire are connected together to form the warp-knitted fabric, weft-knitted fabric, woven fabric, braided fabric, cable, circular-warp-knitted fabric or circular-weft-knitted fabric.

12. The method according to claim 8, wherein the fine metal wire or wires constituting the structure are selected from the group consisting of fine metal wires of copper, copper-based alloys, silver, silver-based alloys, aluminum, aluminum-based alloys, gold-coated silver, aluminum-coated copper and palladium-coated copper.

13. The method according to claim 8, wherein the fine metal wire or wires constituting the structure each have a wire cross-section within a range of 1,950 to 71,000 μm^{2.}
